(19) United States
(12) Patent Application Publication
(10) Pub. No.: US 2019/0278168 A1
(43) Pub. Date: Sep. 12, 2019

(54) FUNCTIONAL FILM LAYER PATTERN, DISPLAY SUBSTRATE, METHOD FOR MANUFACTURING DISPLAY SUBSTRATE, AND DISPLAY DEVICE

(71) Applicant: BOE TECHNOLOGY GROUP CO., LTD., Beijing (CN)

(72) Inventor: Feng Guan, Beijing (CN)

(21) Appl. No.: 16/141,935

(22) Filed: Sep. 25, 2018

(30) Foreign Application Priority Data
Mar. 7, 2018 (CN) 201810187650.X

(51) Int. Cl. G03F 7/00; G03F 7/16; G03F 7/20; G03F 7/32; G03F 7/38; G03F 7/038; G03F 7/039

(52) U.S. Cl. CPC G03F 7/0002; G03F 7/16; G03F 7/2002; G03F 7/039; G03F 7/38; G03F 7/038; G03F 7/32

(57) ABSTRACT

A method for manufacturing a functional film layer pattern is provided. The method includes: forming a first sub-pattern of the functional film layer pattern by an imprint process; forming a second sub-pattern of the functional film layer pattern by a photolithography process, and a line width precision of the second sub-pattern is different from a line width precision of the first sub-pattern.

### CROSS-REFERENCE TO RELATED APPLICATION

The present application claims a priority of the Chinese patent application No. 201810187650.X filed on Mar. 7, 2018, which is incorporated herein by reference in its entirety.

### TECHNICAL FIELD

The present disclosure relates to the field of display technology, in particular to a functional film layer pattern, a display substrate, a method for manufacturing the same and a display device.

### BACKGROUND

Pixels arranged in an array form are driven by a corresponding array circuit so that an image is displayed by a display device. The array circuit usually includes signal lines, transistors, peripheral driving circuits, etc. The more pixels per unit area of the display device there are, the higher the resolution is, and the more delicate the picture that is seen by human eyes is.

With the development of display technology, display devices are developing in the direction of large area, high resolution, and high performance. In the field of manufacturing an existing display device, both functional film layer patterns having line width precision in a nanometer level and functional film layer patterns having line width precision in a micrometer level are formed when manufacturing a display substrate. How to manufacture the functional film layer patterns with different line width precision has become an urgent problem to be solved by those skilled in the art.

### SUMMARY

In one aspect, the present disclosure provides in some embodiments a method for manufacturing a functional film layer pattern, including: forming a first sub-pattern of the functional film layer pattern by an imprint process; and forming a second sub-pattern of the functional film layer pattern by a photolithography process, wherein a line width precision of the second sub-pattern is different from a line width precision of the first sub-pattern.

In some embodiments, the method specifically includes: forming a layer of functional film layer material having a photoresist property; providing a mask including a light transmitting substrate, and an imprint pattern and a mask pattern on the light transmitting substrate, the line width precision of the imprint pattern being a first precision, and the line width precision of the mask pattern being a second precision, and the first precision being larger than the second precision; imprinting the layer of functional film layer material with the imprint pattern of the mask, and curing the layer of functional film layer material to form the first sub-pattern having a line width precision of the first precision; and exposing and developing the layer of functional film layer material with a mask pattern of the mask, to form a second sub-pattern having a line width precision of the second precision.

In some embodiments, the functional film layer material is a negative photoresist material, the mask pattern includes an opaque pattern, and an orthographic projection of the opaque pattern on the light transmitting substrate does not overlap an orthographic projection of the imprint pattern on the light transmitting substrate; and the layer of functional film layer material is cured by light passing through the mask during the exposure process.

In some embodiments, the functional film layer material is a positive photoresist material, the mask pattern includes an opaque pattern, and an orthographic projection of the imprint pattern on the light transmitting substrate is within an orthographic projection of the opaque pattern on the light transmitting substrate; and the layer of function film layer material is cured by thermal curing.

In some embodiments, the method specifically includes: forming a layer of functional film layer material; forming an imprint adhesive layer having a photoresist property on the layer of functional film layer material; providing a mask including a light transmitting substrate and an imprint pattern and a mask pattern on the light transmitting substrate, the line width precision of the imprint pattern being a first precision, and a line width precision of the mask pattern being a second precision, and the first precision being larger than the second precision; imprinting the imprinting adhesive layer with an imprint pattern of the mask, and curing the imprint adhesive layer to form a first imprint adhesive pattern having a line width precision of the first precision; exposing and developing the imprint adhesive layer with a mask pattern of the mask, to form a second imprint adhesive pattern having a line width precision of the second precision; etching the functional film layer material that is not covered by the first imprint adhesive pattern and the second imprint adhesive pattern to form the functional film layer pattern, the functional film layer pattern includes a first sub-pattern having a line width precision of the first precision and a second sub-pattern having a line width precision of the second precision; and stripping the first imprint adhesive pattern and the second imprint adhesive pattern.

In some embodiments, the imprint adhesive layer is made of a negative photoresist material, the mask pattern includes an opaque pattern, and an orthographic projection of the opaque pattern on the light transmitting substrate does not overlap an orthographic projection of the imprint pattern on the light transmitting substrate; and the first imprint adhesive pattern is cured by light passing through the mask during the exposure process.

In some embodiments, the imprint adhesive layer is made of a positive photoresist material, the mask pattern includes an opaque pattern, and an orthographic projection of the imprint pattern on the light transmitting substrate is within an orthographic projection of the opaque pattern on the light transmitting substrate; and the imprint adhesive layer is cured by thermal curing.

In some embodiments, imprint adhesive remains in an imprint adhesive completely removed region between adjacent first imprint adhesive patterns, and before the functional film layer material that is not covered by the first imprint adhesive pattern and the second imprint adhesive pattern is etched, the method further includes: removing the remained imprint adhesive, and exposing the layer of functional film layer material in the imprint adhesive completely removed region.

In some embodiments, the mask pattern and the imprint pattern are on different surfaces of the mask.

In some embodiments, the first precision is in a nanometer level, and the second precision is in a micrometer level.

In some embodiments, the forming the first sub-pattern of the functional film layer pattern by using an imprint process includes: directly imprinting functional film layer material to form the first sub-pattern, or coating a layer of imprint adhesive on the functional film layer material, imprinting the layer of imprint adhesive to form an imprint adhesive pattern, and etching the functional film layer material by using the imprint adhesive pattern as a mask to form the first sub-pattern.

In some embodiments, an imprint mold used in the imprint process and a mask used in the photolithography process may be a same component or different components.

In some embodiments, the remained imprint adhesive is removed by an ashing process.

In some embodiments, the functional film layer pattern is a Polydimethylsiloxane (PDMS) layer of a microfluidic chip, or a polymethyl methacrylate (PMMA) layer of an optical micro-lens.

In another aspect, a functional film layer pattern is manufactured by the above method.

In another aspect, in a method for manufacturing a display substrate, a functional film layer pattern is formed on the display substrate by the above method.

In another aspect, a display substrate is manufactured by the above method.

In another aspect, a display device includes the above display substrate.

### BRIEF DESCRIPTION OF THE DRAWINGS

FIG. 1 is a flow chart showing a method for manufacturing a functional film layer pattern according to some embodiments of the present disclosure;

FIGS. 2-7 are schematic diagrams showing a method for manufacturing a functional film layer pattern according to some embodiments of the present disclosure.

### DETAILED DESCRIPTION OF THE EMBODIMENTS

In order to make the objects, the technical solutions and the advantages of the present disclosure more apparent, the present disclosure will be described hereinafter in a clear and complete manner in conjunction with the drawings and embodiments.

With the development of display technology, display devices are developing in the direction of large size, high resolution, and high performance. In the field of manufacturing an existing display device, exposure precision is typically controlled in a micrometer level. The high resolution of display devices is limited by the precision of existing exposure equipment, and has become one of the hot concerns for research departments and other manufacture departments.

Nanoimprint technology uses a pattern mask and an imprint adhesive, the precision of the pattern depends entirely on the mask, and can produce a pattern with precision in a nanometer level. However, when manufacturing the display substrate, both a functional film layer pattern having line width precision in a nanometer level and a functional film layer pattern having line width precision in a micrometer level are formed. The line width precision is a magnitude of a width of the functional film layer pattern along a direction perpendicular to the extending direction of the functional film layer pattern, or the line width precision is a linearity degree of a width value in a cross section of a functional film layer pattern along a direction away from the substrate, the cross section is perpendicular to the extending direction of the functional film layer pattern. In order to manufacturing functional film layers with different line width precision, an existing nanoimprint mold is provided with both an imprint pattern with precision in a micron level and an imprint pattern with precision in a nanometer level. When nanoimprint technology is used to produce functional film layers with different line width precision on the substrate, the line width precision from a nanometer level to a micrometer level will cause greater difficulty to the entire imprint process, which will cause that the number of defects is increasing, and the pressure is difficult to control.

The embodiments of the present disclosure provide a functional film layer pattern, a display substrate, a method for manufacturing the same, and a display device, which can realize the manufacture of functional film layer patterns with different line width precision.

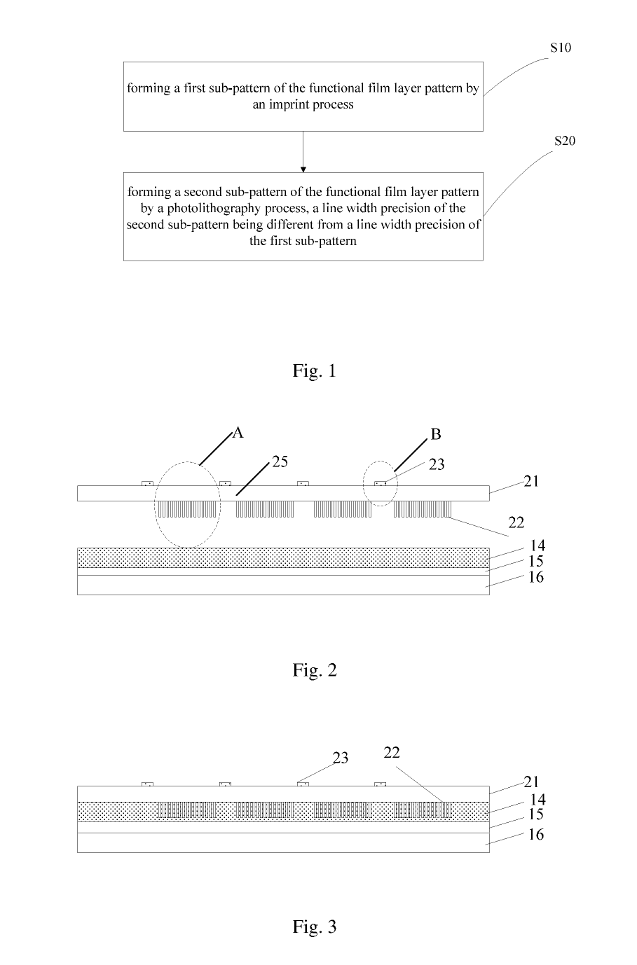

As shown in FIG. 1, some embodiments of the present disclosure provide a method for manufacturing a functional film layer pattern, including: Step 10, forming a first sub-pattern of the functional film layer pattern by an imprint process; and Step 20: forming a second sub-pattern of the functional film layer pattern by a photolithography process, and a line width precision of the second sub-pattern is different from a line width precision of the first sub-pattern.

In some embodiments, a first sub-pattern of the functional film layer pattern is prepared by using an imprint process, and a second sub-pattern of the functional film layer pattern is prepared by a photolithography process, and a line width precision of the second sub-pattern is different from the line width precision of the first sub-pattern, thereby realizing the manufacture of the functional film layer pattern with different line width precision. Moreover, since the precision of the imprinted pattern is high, the first sub-pattern with higher precision can be prepared by the imprint process, and the second sub-pattern with lower precision can be prepared by the lithography process, thereby avoiding the use of the imprint process to produce the functional film layer pattern with different line width precision simultaneously. The difficulty of the imprint process is reduced and the number of defects is decreased, meanwhile the functional film layer patterns with higher line width precision are manufactured.

The functional film layer pattern manufactured by the technical solution of some embodiments can be applied to the display substrate or an optical component. Specifically, the functional film layer pattern can be a Polydimethylsiloxane (PDMS) layer of a microfluidic chip, a polymethyl methacrylate (PMMA) layer of an optical micro-lens, or the like.

Forming the first sub-pattern of the functional film layer pattern by using an imprint process includes directly imprinting the functional film layer material to form the first sub-pattern, or coating a layer of imprint adhesive on the functional film layer material, imprinting the imprint adhesive to form an imprint adhesive pattern, and etching the functional film layer material by using the imprint adhesive pattern as a mask to form a first sub-pattern.

In addition, it is also possible to separately form patterns having different structures by using an imprint process and a photolithography process, for example, it is difficult to form a pattern having a spherical structure by a photolithography process, and a pattern having a spherical structure can be formed by an imprint process. Therefore, the first sub-pattern having a cross section of a spherical shape in a direction perpendicular to the substrate can be formed by an imprint process, and the second sub-pattern having a cross section of a trapezoid, a rectangle or a triangle shape in a direction perpendicular to the substrate can be formed by a photolithography process.

The imprint mold used in the imprint process and the mask used in the photolithography process may be a same component or different components. When the imprint mold used in the imprint process is the same component as the mask used in the photolithography process, the pattern of the functional film layer can be formed by using a specific mask.

In some embodiments, when the material of the functional film layer has a photoresist property, the step of forming the functional film layer pattern includes: forming a layer of functional film layer material having a photoresist property; providing a mask including a light transmitting substrate, and an imprint pattern and a mask pattern on the light transmitting substrate, the line width precision of the imprint pattern being a first precision, and the line width precision of the mask pattern being the second precision, and the first precision is larger than the second precision; imprinting the layer of functional film layer material with an imprint pattern of the mask, and curing the imprinted functional film layer material to form the first sub-pattern having a line width precision of the first precision; exposing and developing the layer of functional film layer material with a mask pattern of the mask so as to form a second sub-pattern having a line width precision of the second precision.

The surface of the light transmitting substrate is provided with an imprint pattern having a line width precision of the first precision, and the surface of the light transmitting substrate is further provided with a mask pattern having a line width precision of a second precision. The mask pattern and the imprint pattern may be located on a same surface or on different surfaces, so that when the functional film layer pattern is prepared on the substrate, the first sub-pattern with the line width precision of the first precision can be prepared by the imprint process by using the imprint pattern on the mask, the second sub-pattern with the width line in the second precision is prepared by the photolithography process by using the mask pattern on the mask. Since the precision of the imprint pattern is higher, the first sub-pattern with higher precision can be prepared by the imprint process, and the second sub-pattern with lower precision can be prepared by the photolithography process, thereby avoiding the imprint process to be used to simultaneously prepare functional film layers with different line width precisions. It reduces the difficulty of the imprint process and reduces the number of defects, while also realizing the production of functional film layer patterns with higher line width precision. In addition, a same mask is used in the imprint process and the photolithography process, and the mask is not replaced, the production time can be saved, the production efficiency of the display substrate can be improved, and the production cost of the display substrate can be reduced.

After the layer of imprinted functional film layer material is cured, the functional film layer material may be remained in a functional film layer material completely removed region between adjacent first sub-patterns, and therefore, after the second sub-pattern is formed by exposure and development processes, the first sub-pattern and the second sub-pattern may be integrally thinned by an ashing process to remove the functional film layer material remained in the functional film layer material completely removed region.

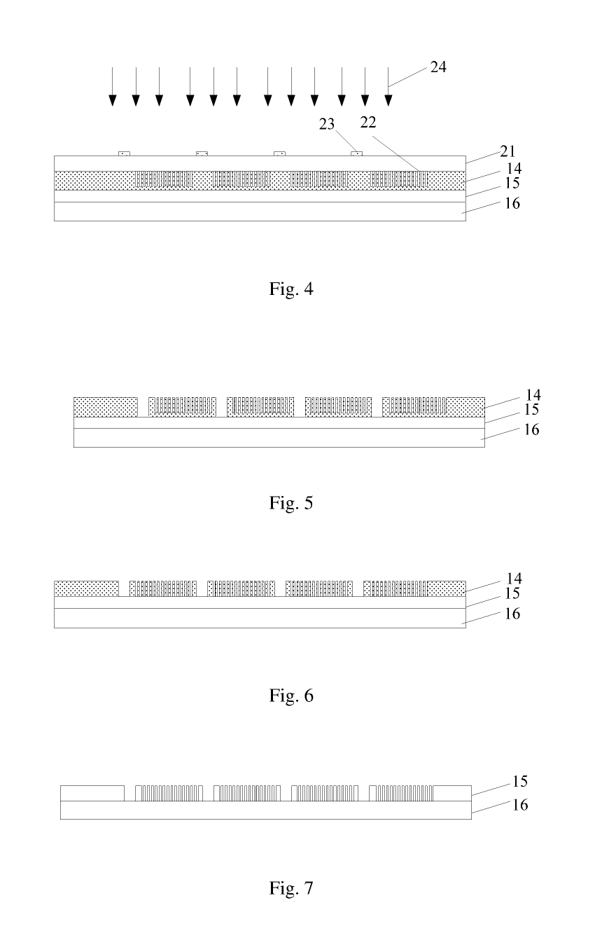

FIG. 2 shows a mask used in some embodiments of the present disclosure. A refers to an imprint pattern, B refers to a mask pattern, and the imprint pattern is used to prepare a first sub-pattern, and the imprint pattern includes bulges and the gap between the bulges, the imprint pattern on the mask 21 can be transferred to the layer of functional film layer material to form the first sub-pattern by the imprint process.

Specifically, the first precision is in the nanometer level and the second precision is in the micrometer level. Thus, the functional film layer pattern with the line width precision in the nanometer level and the functional film layer pattern with the line width precision in the micrometer level can be simultaneously prepared by using the mask plate in some embodiments of the disclosure, and when the functional film layer pattern is applied to the display device, a high resolution may be achieved. Of course, the first precision is not limited to a precision in a nanometer level, and the second precision is not limited to a precision in a micrometer level, and may be other levels of precision.

In some embodiments, the functional film layer material is a negative photoresist material, and the mask pattern on the mask includes an opaque pattern, and the orthographic projection of the opaque pattern on the light transmitting substrate does not overlap the orthographic projection of the imprint pattern on the light transmitting substrate, so that after the imprint pattern is transferred onto the layer of functional film layer material by the imprint process to form the first sub-pattern with the line width precision of the first precision, the first sub-pattern may not be cured, and when the exposure process is implemented by the mask pattern on the mask, the layer of the functional film layer material can be cured by light passing through the mask during the exposure process. The imprint adhesive may be cured at the same time of the exposure process, which can save production time. The exposure process includes, but is not limited to, an ultraviolet light exposure process, a visible light exposure process, and an electron beam exposure process.

The mask pattern includes an opaque pattern, an orthographic projection of the opaque pattern on the light transmitting substrate does not overlap an orthographic projection of the imprint pattern on the light transmitting substrate. When the functional film layer material is a negative photoresist material, the forming of the functional film layer pattern includes: imprinting the layer of functional film layer material with an imprint pattern of the mask, to form the first sub-pattern having a line width precision of a first precision; exposing and developing the layer of functional film layer material by using a mask pattern of the mask, and simultaneously curing the first sub-pattern by the ultraviolet light passing through the mask during the exposure process, to form the second sub-pattern having a line width precision of a second precision.

In some embodiments, the functional film layer material is a positive photoresist material, and the mask pattern of the mask includes an opaque pattern, and the orthographic projection of the imprint pattern on the light transmitting substrate is within the orthographic projection of the opaque pattern on the light transmitting substrate. After the imprint pattern is transferred onto the imprint adhesive by the imprint process to form the first sub-pattern with the line width precision of the first precision, the first sub-pattern needs to be cured first, and then the layer of the functional film material is exposed by the mask pattern of the mask, and developed to form a second sub-pattern having a line width precision of a second precision. Specifically, the first sub-pattern may be cured by thermal curing.

When the mask pattern includes an opaque pattern, and an orthographic projection of the imprint pattern on the light transmitting substrate is within an orthographic projection of the opaque pattern on the light transmitting substrate, the steps of forming the functional film layer pattern specifically include: imprinting the layer of functional film layer material with an imprint pattern of the mask to form the first sub-pattern having a line width precision of a first precision; curing the first sub-pattern; exposing and developing the layer of functional film layer material by a mask pattern of the mask, to form the second sub-pattern having a line width precision of a second precision.

In some embodiments, when the layer of functional film layer material does not have a photoresist property, the step of forming the functional film layer pattern specifically includes: forming a layer of functional film layer material; forming an imprint adhesive layer having a photoresist property on the layer of functional film layer material; providing a mask including a light transmitting substrate and an imprint pattern and a mask pattern on the light transmitting substrate, the line width precision of the imprint pattern being a first precision, and a line width precision of the mask pattern being the second precision, and the first precision being larger than the second precision; imprinting the imprinting adhesive layer with an imprint pattern of the mask, and curing the imprint adhesive layer to form a first imprint adhesive pattern having a line width precision of a first precision; exposing and the developing the imprint adhesive layer with a mask pattern of the mask, to form a second imprint adhesive pattern having a line width precision of a second precision; etching the functional film layer material that is not covered by the first imprint adhesive pattern and the second imprint adhesive pattern to form the functional film layer pattern, the functional film layer pattern includes a first sub-pattern having a line width precision of a first precision and a second sub-pattern having a line width precision of a second precision; stripping the first imprint adhesive pattern and the second imprint adhesive pattern.

The surface of the light transmitting substrate of the mask is provided with an imprint pattern having a line width precision of the first precision, and the surface of the light transmitting substrate is further provided with a mask pattern having a line width precision of a second precision. The mask pattern and the imprint pattern may be located on a same surface or on different surfaces, so that when the functional film layer pattern is formed on the substrate, the first sub-pattern with the line width precision of the first precision can be prepared by the imprint process by using the imprint pattern on the mask, the second sub-pattern with the width line in the second precision is prepared by the photolithography process by using the mask pattern on the mask. Since the precision of the imprint pattern is higher, the first sub-pattern with higher precision can be formed by the imprint process, and the second sub-pattern with lower precision can be formed by the photolithography process, thereby avoiding the imprint process to be used to simultaneously form functional film layers with different line width precisions. It reduces the difficulty of the imprint process and reduces the number of defects, while also realizing the production of functional film layer patterns with higher line width precision. In addition, a same mask is used in the imprint process and the photolithography process, and the mask is not replaced, the production time can be saved, the production efficiency of the display substrate can be improved, and the production cost of the display substrate can be reduced.

FIG. 2 shows a mask 21 used in some embodiments of the present disclosure. A refers to an imprint pattern, B refers to a mask pattern, and the imprint pattern is used to prepare a first sub-pattern, and the imprint pattern includes bulges and the gap between the bulges, the imprint pattern on the mask 21 can be transferred to the imprint adhesive layer to form the first imprint adhesive pattern by the imprint process.

Specifically, the first precision is in the nanometer level and the second precision is in the micrometer level. Thus, the functional film layer pattern with the line width precision in the nanometer level and the functional film layer pattern with the line width precision in the micrometer level can be simultaneously prepared by using the mask in some embodiments of the disclosure, and when the functional film layer pattern is applied to the display device, a high resolution may be achieved. Of course, the first precision is not limited to a precision in a nanometer level, and the second precision is not limited to a precision in a micrometer level, and may be other levels of precision.

In some embodiments, the imprint adhesive layer is made of a negative photoresist material, and the mask pattern on the mask includes an opaque pattern, and the orthographic projection of the opaque pattern on the light transmitting substrate does not overlap the orthographic projection of the imprint pattern on the light transmitting substrate, so that after the imprint pattern is transferred onto the imprint adhesive layer by the imprint process to form the first imprint adhesive pattern with the line width precision of the first precision, the first imprint adhesive pattern may not be cured, and when exposure is implemented by the mask pattern on the mask, the imprint adhesive layer can be cured by light passing through the mask during the exposure process. The imprint adhesive may be cured at the same time of the exposure process, which can save production time. The exposure process includes, but is not limited to, an ultraviolet light exposure process, a visible light exposure process, and an electron beam exposure process.

The mask pattern of the mask includes an opaque pattern; an orthographic projection of the opaque pattern on the light transmitting substrate does not overlap an orthographic projection of the imprint pattern on the light transmitting substrate. When the imprint adhesive layer is made of a negative photoresist material, the forming the functional film layer pattern includes: imprinting the imprint adhesive layer with an imprint pattern of the mask, to form the first imprint adhesive pattern having a line width precision of a first precision; exposing the imprint adhesive layer by using a mask pattern of the mask, and simultaneously curing the first imprint adhesive pattern by the ultraviolet light passing through the mask during the exposure process; developing to form the second imprint adhesive pattern having a line width precision of a second precision; etching a functional film layer material that is not covered by the first imprint adhesive pattern and the second imprint adhesive pattern to form the functional film layer pattern, the functional film layer pattern includes a first sub-pattern having a line width precision of a first precision and a second sub-pattern having a line width precision of a second precision.

In some embodiments, the imprint adhesive layer is made of a positive photoresist material, and the mask pattern of the mask includes an opaque pattern, and the orthographic projection of the imprint pattern on the light transmitting substrate is within the orthographic projection of the opaque pattern on the light transmitting substrate. After the imprint pattern is transferred onto the imprint adhesive by the imprint process to form the first imprint adhesive pattern with the line width precision of the first precision, the imprint adhesive needs to be cured, and then the imprint adhesive layer is exposed by the mask pattern of the mask, and developed to form a second imprint adhesive pattern having a line width precision of a second precision. Specifically, the first imprint adhesive pattern may be cured by thermal curing.

When the mask pattern of the mask includes an opaque pattern, and an orthographic projection of the imprint pattern on the light transmitting substrate is within an orthographic projection of the opaque pattern on the light transmitting substrate, the steps of forming the functional film layer pattern specifically include: imprinting the imprint adhesive layer with an imprint pattern of the mask to form the first imprint adhesive pattern having a line width precision of a first precision; curing the first imprint adhesive pattern; exposing and developing the imprint adhesive layer by a mask pattern of the mask, to form the second imprint adhesive pattern having a line width precision of a second precision; etching a functional film layer material that is not covered by the first imprint adhesive pattern and the second imprint adhesive pattern to form the functional film layer pattern, the functional film layer pattern includes a first sub-pattern having a line width precision of a first precision and a second sub-pattern having a line width precision of a second precision.

In the above embodiment, the imprint adhesive pattern is cured by ultraviolet light, but the imprint adhesive pattern is not limited to ultraviolet light, and may be other wavelengths of light.

Further, imprint adhesive is remained in an imprint adhesive completely removed region between the adjacent first imprint adhesive patterns, and before the functional film layer material that is not covered by the first imprint adhesive pattern and the second imprint adhesive pattern is etched, the method further includes: removing the remained imprint adhesive, and exposing the layer of functional film layer material in the imprint adhesive completely removed region.

Specifically, the remained imprint adhesive can be removed by an ashing process.

The method for forming the functional film layer pattern is described in detail below with reference to the accompanying drawings. As shown in FIG. 2 to FIG. 7, the forming the functional film layer pattern on a base substrate specifically includes the following steps.

Step 1: As shown in FIG. 2, a layer of functional film layer material 15 is formed on the base substrate 16, and an imprint adhesive layer 14 having a photoresist property is coated on the layer of functional film layer material 15, a mask 21 is provided.

The functional film layer material is determined based on the material of the functional film layer pattern to be formed. For example, if the functional film layer pattern to be formed is a signal line, the functional film layer material is a metal material or a transparent conductive material. If the functional film layer pattern to be formed is an insulating layer, the functional film layer material is an oxide, a nitride or an oxynitride or the like.

The imprint adhesive layer 14 may be made of a positive photoresist or a negative photoresist. This embodiment is described by using the imprint adhesive layer 14 as a negative photoresist.

The mask 21 includes a light transmitting substrate 25, an imprint pattern 22 on a surface of the light transmitting substrate 25 close to the base substrate, and a mask pattern 23 on a surface of the light transmitting substrate 25 away from the base substrate, the imprint pattern has a line width precision in a nanometer level; the mask pattern 23 has a line width precision in a micrometer level, and the mask pattern 23 is an opaque pattern. As can be seen from FIG. 1, the mask pattern 23 and the imprint pattern 22 are arranged on different surfaces of the light transmitting substrate 25. The orthographic projection of the mask pattern 23 on the light transmitting substrate 25 and the orthographic projection of the imprint pattern 22 on the light transmitting substrate 25 do not overlap.

Step 2: as shown in FIG. 3, the imprint adhesive layer 14 is imprinted by the imprint pattern 22 on the surface of the mask 21, to form the first imprint adhesive pattern having a line width precision in the nanometer level.

Step 3: as shown in FIG. 4, the imprint adhesive layer 14 is exposed by the ultraviolet light 24 irradiated on the surface of the mask 21. Since the imprint adhesive layer 14 is negative photoresist, a second imprint adhesive pattern with a line width precision in the micrometer level is formed after the development process, and the second imprint adhesive pattern includes an imprint adhesive reserving area and an imprint adhesive removing area, and the first imprint adhesive pattern having a line width precision in the nanometer level is cured by ultraviolet light 24. Before the first imprint adhesive pattern is cured, the mask 21 cannot be separated from the imprint adhesive layer 14 because the imprint adhesive pattern has not a fixed shape.

Step 4. After the curing is completed and the mask 21 is removed, a structure as shown in FIG. 5 is formed. It can be seen that a certain thickness of the imprint adhesive layer is remained at the bottom of the imprint adhesive completely removed region between the adjacent first imprint adhesive patterns, and the imprint adhesive in the imprint adhesive completely removed region should be completely removed. The imprint adhesive is remained for protecting the functional film layer material. Therefore, before the etching the functional film layer material, the first imprint adhesive pattern and the second imprint adhesive pattern are integrally thinned by an ashing process to remove the remained imprint adhesive. As shown in FIG. 6, only the first imprint adhesive pattern and the second imprint adhesive are remained on the layer of functional film layer material 15 after the ashing process. The layer of functional film layer material 15 in the imprint adhesive completely removed region can be exposed;

Step 5: as shown in FIG. 7, the layer of functional film layer material 15 that is not covered by the first imprint adhesive pattern and the second imprint adhesive pattern is etched to form a functional film layer pattern, and the functional film layer pattern includes the first sub-pattern with line width precision in a nanometer level and the second sub-pattern with line width precision in a micrometer level. Finally, the first imprint adhesive pattern and the second imprint adhesive pattern are stripped.

Through the above steps 1-5, the second sub-pattern with the line width precision in the micrometer level and the first sub-pattern with the line width precision in the nanometer level can be formed, and the high resolution of the display device can be realized. In addition, a same mask 21 is used in the imprint process and the photolithography process, and the mask is not replaced, the production time can be saved, the production efficiency of the display substrate can be improved, and the production cost of the display substrate can be reduced.

A functional film layer pattern which is produced by the above-described manufacturing method is further provided.

A method for preparing a display substrate on which a functional film layer pattern is formed by the method described above is provided.

A display substrate which is prepared by the above-described method is provided.

A functional film layer pattern having two different line width precisions is on a substrate.

Specifically, the line width precision of the first sub-pattern is the first precision, the line width precision of the second sub-pattern is the second precision, the first precision may be in the nanometer level, and the second precision may be in the micrometer level. In this way, the functional film layer pattern having the line width precision in the nanometer level and the functional film layer pattern having the line width precision in the micrometer level are on the substrate, thereby realizing the high resolution of the display device. Of course, the first precision is not limited to a precision in the nanometer level, and the second precision is not limited to a precision in the micrometer level, and may be other levels of precision.

Some embodiments of the present disclosure also provide a display device including the display substrate as described above. The display device may be any product or component having a display function, such as a television, a display, a digital photo frame, a mobile phone, a tablet computer, etc. The display device further includes a flexible circuit board, a printed circuit board, and a backboard.

In the method in some embodiments of the present disclosure, the order of the steps is not used to limit the steps. For those skilled in the art, the change of the step orders is performed without any creative work and is also within the scope of the present disclosure.

Unless otherwise defined, technical terms or scientific terms used in the present disclosure are intended to be understood in the ordinary meaning of those of ordinary skill in the art. The words “first,” “second,” and similar terms used in the present disclosure do not denote any order, quantity, or importance, but are used to distinguish different components. The words “including” or “comprising”, and the like, are intended to mean that an element before the word includes elements after the word and some equivalent elements, and does not exclude other elements. The words “coupled” or “connected” and the like are not limited to physical or mechanical connections, but may include electrical connections, whether direct or indirect. “Upper”, “lower”, “left”, “right”, etc. are only used to indicate the relative positional relationship, and when the absolute position of the object to be described is changed, the relative positional relationship may also change accordingly.

It will be understood that when an element such as a layer, a film, a region or a substrate is referred to as being “on” or “below”, it may be directly on or below, or through some intermediate elements.

The above is an alternative embodiment of the present disclosure, and it should be noted that those skilled in the art can also make further improvements and modifications without departing from the principles of the present disclosure. It should also be within the scope of protection of the present disclosure.

What is claimed is:

1. A method for manufacturing a functional film layer pattern, comprising:
forming a first sub-pattern of the functional film layer pattern by an imprint process; and
forming a second sub-pattern of the functional film layer pattern by a photolithography process,
wherein a line width precision of the second sub-pattern is different from a line width precision of the first sub-pattern.

2. The method according to claim 1, specifically comprising:
forming a layer of functional film layer material having a photoresist property;
providing a mask including a light transmitting substrate, and an imprint pattern and a mask pattern on the light transmitting substrate, a line width precision of the imprint pattern being a first precision, and a line width precision of the mask pattern being a second precision, and the first precision being larger than the second precision;
imprinting the layer of functional film layer material with the imprint pattern of the mask, and curing the layer of functional film layer material to form the first sub-pattern having line width precision of the first precision; and
exposing and developing the layer of functional film layer material with a mask pattern of the mask, to form the second sub-pattern having line width precision of the second precision.

3. The method according to claim 2, wherein:
the functional film layer material is a negative photoresist material;
the mask pattern includes an opaque pattern, and an orthographic projection of the opaque pattern on the light transmitting substrate does not overlap an orthographic projection of the imprint pattern on the light transmitting substrate; and
the layer of functional film layer material is cured by light passing through the mask during the exposure process.

4. The method according to claim 2, wherein:
the functional film layer material is a positive photoresist material,
the mask pattern includes an opaque pattern, and an orthographic projection of the imprint pattern on the light transmitting substrate is within an orthographic projection of the opaque pattern on the light transmitting substrate; and
the layer of function film layer material is cured by thermal curing.

5. The method according to claim 1, specifically comprising:
forming a layer of functional film layer material;
forming an imprint adhesive layer having a photoresist property on the layer of functional film layer material;
providing a mask including a light transmitting substrate and an imprint pattern and a mask pattern on the light transmitting substrate, a line width precision of the imprint pattern being a first precision, and a line width precision of the mask pattern being a second precision, and the first precision being larger than the second precision;
imprinting the imprinting adhesive layer with an imprint pattern of the mask, and curing the imprint adhesive layer to form a first imprint adhesive pattern having line width precision of the first precision;
exposing and developing the imprint adhesive layer with a mask pattern of the mask, to form a second imprint adhesive pattern having line width precision of the second precision;
etching the functional film layer material that is not covered by the first imprint adhesive pattern and the second imprint adhesive pattern to form the functional film layer pattern, the functional film layer pattern including a first sub-pattern having line width precision of the first precision and a second sub-pattern having line width precision of the second precision; and
stripping the first imprint adhesive pattern and the second imprint adhesive pattern.

6. The method according to claim 5, wherein:
the imprint adhesive layer is made of a negative photoresist material,
the mask pattern includes an opaque pattern, and an orthographic projection of the opaque pattern on the light transmitting substrate does not overlap an orthographic projection of the imprint pattern on the light transmitting substrate; and
the first imprint adhesive pattern is cured by light passing through the mask during the exposure process.

7. The method according to claim 5, wherein:
the imprint adhesive layer is made of a positive photoresist material,
the mask pattern includes an opaque pattern, and an orthographic projection of the imprint pattern on the light transmitting substrate is within an orthographic projection of the opaque pattern on the light transmitting substrate; and
the imprint adhesive layer is cured by thermal curing.

8. The method according to claim 5, wherein imprint adhesive remains in an imprint adhesive completely removed region between adjacent first imprint adhesive patterns, and before the functional film layer material that is not covered by the first imprint adhesive pattern and the second imprint adhesive pattern is etched, and the method further comprises:
removing the remaining imprint adhesive, and exposing the layer of functional film layer material in the imprint adhesive completely removed region.

9. The method according to claim 2, wherein the mask pattern and the imprint pattern are on different surfaces of the mask.

10. The method according to claim 2, wherein the first precision is of a nanometer level, and the second precision is of a micrometer level.

11. The method according to claim 1, wherein forming the first sub-pattern of the functional film layer pattern by using an imprint process comprises:
directly imprinting functional film layer material to form the first sub-pattern; or
coating a layer of imprint adhesive on functional film layer material, imprinting the layer of imprint adhesive to form an imprint adhesive pattern, and etching the functional film layer material by using the imprint adhesive pattern as a mask to form the first sub-pattern.

12. The method according to claim 1, wherein an imprint mold used in the imprint process and a mask used in the photolithography process are a same component.

13. The method according to claim 8, wherein the remaining imprint adhesive is removed by an ashing process.

14. The method according to claim 1, wherein the functional film layer pattern is a Polydimethylsiloxane (PDMS) layer of a microfluidic chip, or a polymethyl methacrylate (PMMA) layer of an optical micro-lens.

15. The method according to claim 5, wherein the mask pattern and the imprint pattern are on different surfaces of the mask.

16. The method according to claim 5, wherein the first precision is of a nanometer level, and the second precision is of a micrometer level.

17. A functional film layer pattern, manufactured by the method according to claim 1.

18. A method for manufacturing a display substrate, wherein the display substrate comprises a base substrate, and a functional film layer pattern is formed on the base substrate by the method according to claim 1.

19. A display substrate, manufactured by the method according to claim 18.

20. A display device, wherein the display device comprises the display substrate according to claim 19.
